(19) United States
(12) Patent Application Publication
(10) Pub. No.: US 2021/0408305 A1
(43) Pub. Date: Dec. 30, 2021

(54) INORGANIC COMPOUND SEMICONDUCTOR, METHOD FOR MANUFACTURING SAME, AND LIGHT ENERGY CONVERSION ELEMENT USING SAME

(71) Applicant: Panasonic Intellectual Property Management Co., Ltd., Osaka (JP)

(72) Inventors: RYOSUKE KIKUCHI, Osaka (JP); TORU NAKAMURA, Osaka (JP); KOKI UENO, Osaka (JP); TAKAHIRO KURABUCHI, Osaka (JP); YASUSHI KANEKO, Osaka (JP); KAZUHITO HATO, Osaka (JP); FUMIYASU OBA, Kanagawa (JP); YU KUMAGAI, Kanagawa (JP)

(21) Appl. No.: 17/474,682

(22) Filed: Sep. 14, 2021

Related U.S. Application Data
(63) Continuation of application No. PCT/JP2019/024580, filed on Jun. 20, 2019.

(30) Foreign Application Priority Data
Mar. 28, 2019 (JP) 2019-063757

(51) Int. Cl. H01L 31/032; H01L 31/0725; H01L 31/18

(52) U.S. Cl. CPC H01L 31/032; H01L 31/18; H01L 31/0725

(57) ABSTRACT

An inorganic compound semiconductor of the present disclosure contains yttrium, zinc, and nitrogen.

### BACKGROUND

### 1. Technical Field

The present disclosure relates to an inorganic compound semiconductor, a method for manufacturing an inorganic compound semiconductor, and a light energy conversion element using the same.

### 2. Description of the Related Art

When a semiconductor is irradiated with light having an energy higher than the band gap of the semiconductor, electron-hole pairs are generated in the semiconductor. The semiconductor is used for (i) a solar cell or a photodetector which outputs electric energy by separating the pairs described above or (ii) a hydrogen manufacturing device which manufactures hydrogen by water splitting using the pairs described above for a chemical reaction of water splitting.

In “Photovoltaic materials: Present efficiencies and future challenges”, Science, 352, aad4424 (2016), by Polman A. et al., conversion efficiencies of solar cells using semiconductor materials having various band gaps have been disclosed. As one example, according to the above non-patent document, a single junction solar cell using GaInP having a band gap of 1.81 eV has a conversion efficiency of 20.8%.

In “Conversion efficiency limits and band gap designs for multi-junction solar cells with internal radiative efficiencies below unity”, Optics Express, Vol. 24, A740-A751 (2016), by Lin Z. et al., band gaps of semiconductors suitable for solar cells have been disclosed. The above non-patent document has disclosed a multi-junction type solar cell in which at least two types of semiconductors having different band gaps are laminated to each other as light energy conversion layers. According to the above non-patent document, in a tandem type solar cell in which two types of semiconductors having different band gaps are laminated to each other, a band gap of a semiconductor for a first light energy conversion layer located most outside is preferably approximately 1.7 eV, and a band gap of a semiconductor for a second light energy conversion layer located at a rear side of the first light energy conversion layer is preferably approximately 1.1 eV. Furthermore, according to the above non-patent document, in a tandem type solar cell in which three types of semiconductors having different band gaps are laminated to each other, a band gap of a semiconductor for a first light energy conversion layer located most outside is preferably approximately 1.9 eV, a band gap of a semiconductor for a second light energy conversion layer located at a rear side of the first light energy conversion layer is preferably approximately 1.4 eV, and a band gap of a semiconductor for a third light energy conversion layer located at a rear side of the second light energy conversion layer is preferably approximately 1.0 eV.

In “Modeling Practical Performance Limits of Photoelectrochemical Water Splitting Based on the Current State of Materials Research”, ChemSusChem, Vol. 7, 1372-1385 (2014), by Linsey C. Seitz et al., a band gap of a semiconductor suitable for water splitting (hereinafter, referred to as “solar water splitting” in some cases) by solar energy has been disclosed. Furthermore, the above non-patent document has also disclosed a device having a tandem type structure in which two types of semiconductors having different band gaps are laminated to each other. According to the above non-patent document, in the device having a tandem type structure, a band gap of a semiconductor of a top cell located at a light incident side is preferably approximately 1.8 eV, and a band gap of a semiconductor of a bottom cell is preferably approximately 1.2 eV.

In “All Solution-Processed Lead Halide Perovskite-BiVO₄ Tandem Assembly for Photolytic Solar Fuels Production”, J. Am. Chem. Soc. 137, 974-981 (2015), by Chen, Y.-S. et al., a solar water splitting device having a tandem type structure in which two types of semiconductors having different band gaps are laminated to each other has been disclosed. This non-patent document has also disclosed that in this solar water splitting device, a water splitting reaction is actually carried out by pseudo-solar light radiation.

### SUMMARY

One non-limiting and exemplary embodiment provides a novel inorganic compound semiconductor.

In one general aspect, the techniques disclosed here feature an inorganic compound semiconductor containing yttrium, zinc, and nitrogen.

The present disclosure provides a novel inorganic compound semiconductor. The novel inorganic compound semiconductor according to the present disclosure is able to convert light into electric energy.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 shows a crystal structure of YZn₃N₃;

FIG. 2 shows an absorption coefficient spectrum of YZn₃N₃ calculated by the first-principles calculation method;

FIG. 3 shows a phase diagram of a chemical potential space of a Y—Zn—N coordinate system;

FIG. 4 is a cross-sectional view of a light energy conversion element according to a second embodiment;

FIG. 5 is a cross-sectional view of a device according to a third embodiment;

FIG. 6 is a cross-sectional view of a device according to a fourth embodiment;

FIG. 7 is a cross-sectional view of a modified example of the device according to the fourth embodiment;

FIG. 8 shows an actual oblique incident X-ray diffraction pattern of a thin film of Sample 1 and an X-ray diffraction pattern of YZn₃N₃ calculated using a crystal structure predicted by the first-principles calculation method;

FIG. 9A shows an absorption coefficient spectrum of the thin film of Sample 1;

FIG. 9B shows a Tauc plot (hν vs. (ahν)²) of the absorption coefficient spectrum of the thin film of Sample 1;

FIG. 10 shows an actual oblique incident X-ray diffraction pattern of a thin film of Sample 2 and the X-ray diffraction pattern of YZn₃N₃ calculated using the crystal structure predicted by the first-principles calculation method;

FIG. 11A shows an absorption coefficient spectrum of the thin film of Sample 2;

FIG. 11B shows a Tauc plot (hν vs. (ahν)²) of the absorption coefficient spectrum of the thin film of Sample 2;

FIG. 12 shows an actual oblique incident X-ray diffraction pattern of a thin film of Sample 3 and the X-ray diffraction pattern of YZn₃N₃ calculated using the crystal structure predicted by the first-principles calculation method;

FIG. 13A shows an absorption coefficient spectrum of the thin film of Sample 3;

FIG. 13B shows a Tauc plot (hν vs. (ahν)²) of the absorption coefficient spectrum of the thin film of Sample 3;

FIG. 14 shows an actual oblique incident X-ray diffraction pattern of a thin film of Sample 4 and the X-ray diffraction pattern of YZn₃N₃ calculated using the crystal structure predicted by the first-principles calculation method;

FIG. 15A shows an absorption coefficient spectrum of the thin film of Sample 4; and

FIG. 15B shows a Tauc plot (hν vs. (ahν)²) of the absorption coefficient spectrum of the thin film of Sample 4.

### DETAILED DESCRIPTION

Hereinafter, embodiments of the present disclosure will be described in detail with reference to the drawings.

### First Embodiment

An inorganic compound semiconductor according to a first embodiment of the present disclosure contains yttrium, zinc, and nitrogen. The inorganic compound semiconductor according to the first embodiment is a novel semiconductor material to be usable as a light energy conversion material.

The inorganic compound semiconductor according to the first embodiment may be a compound containing yttrium, zinc, and nitrogen as primary components. When being a compound containing yttrium, zinc, and nitrogen as primary components, the inorganic compound semiconductor according to the first embodiment is able to have a preferable band gap for a light energy conversion layer of a light energy conversion element.

The inorganic compound semiconductor according to the first embodiment may consist essentially of yttrium, zinc, and nitrogen. When consisting essentially of yttrium, zinc, and nitrogen, the inorganic compound semiconductor according to the first embodiment is able to have a preferable band gap for a light energy conversion layer of a light energy conversion element.

The inorganic compound semiconductor consisting essentially of yttrium, zinc, and nitrogen indicates that, in the inorganic compound semiconductor described above, a total molar ratio of yttrium, zinc, and nitrogen is, for example, 95% or more.

The inorganic compound semiconductor according to the first embodiment may be formed from only yttrium, zinc, and nitrogen.

The inorganic compound semiconductor according to the first embodiment may have a hexagonal crystal structure. When having a hexagonal crystal structure, the inorganic compound semiconductor according to the first embodiment is able to have a preferable band gap for a light energy conversion layer of a light energy conversion element.

In the inorganic compound semiconductor according to the first embodiment, a molar ratio of zinc to yttrium may be larger than or equal to 2.5 and smaller than or equal to 6. When the molar ratio described above is larger than or equal to 2.5 and smaller than or equal to 6, the inorganic compound semiconductor according to the first embodiment is able to have a preferable band gap for a light energy conversion layer of a light energy conversion element.

The molar ratio described above may be larger than or equal to 3.0 and smaller than or equal to 4.8. When the molar ratio described above is larger than or equal to 3.0 and smaller than or equal to 4.8, the inorganic compound semiconductor according to the first embodiment is able to have a preferable band gap for a light energy conversion layer of a light energy conversion element.

The inorganic compound semiconductor according to the first embodiment is able to have a band gap of higher than or equal to 1.7 eV and lower than or equal to 2.5 eV. The inorganic compound semiconductor according to the first embodiment can be a preferable light energy conversion material for a light energy conversion layer of a light energy conversion element.

The inorganic compound semiconductor according to the first embodiment may be represented by a chemical formula of YZn₃N₃.

Hereinafter, based on the assumption in that the inorganic compound semiconductor according to the first embodiment is represented by a chemical formula of YZn₃N₃ and has a hexagonal crystal structure, the inorganic compound semiconductor according to the first embodiment will be described.

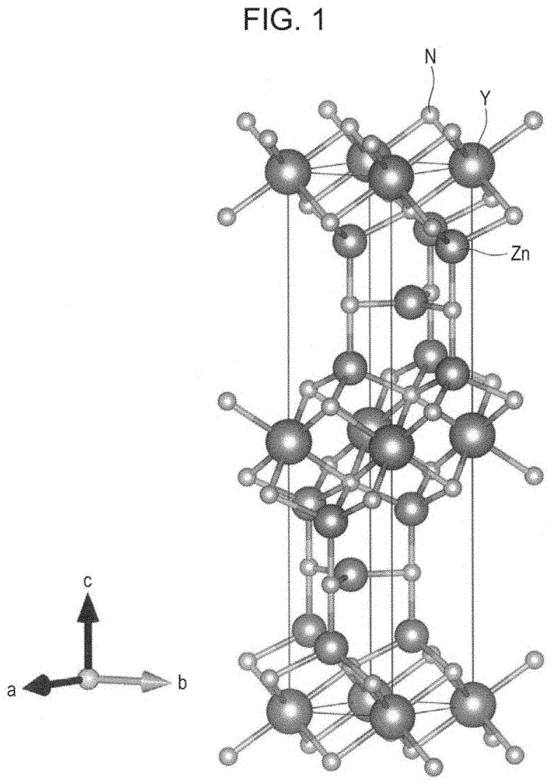

FIG. 1 shows a crystal structure of YZn₃N₃. The crystal of YZn₃N₃ shown in FIG. 1 has a hexagonal system. By using the crystal structure shown in FIG. 1, the geometry optimization of YZn₃N₃ was performed by the first-principles calculation. The first-principles calculation was performed using the PAW (projector augmented wave) method based on the density functional theory. In the geometry optimization and the calculation of an absorption coefficient, the Perdew-Burke-Ernzerhof revised for solids (hereinafter, referred to as “PBEsol”) derived from the generalized gradient approximation (hereinafter, referred to as “GGA”) was used for the description of electron density representing the exchange-correlation term which indicates the interaction between electrons. In the calculation of the band gap, electron effective mass, and hole effective mass, the hybrid functional was used for the description of the electron density representing the exchange-correlation term which indicates the interaction between electrons. In the hybrid functional described above, the Perdew-Burke-Ernzerhof (hereinafter, referred to as “PBE”) exchange energy was partially replaced with the Hartree-Fock exchange energy. It has been known that, by the use of the hybrid functional, a semiconductor physical value, such as the band gap, can be predicted at a high accuracy. For example, when the hybrid functional is used, a semiconductor physical value, such as the band gap, can be predicted at a high accuracy as compared to that in the case in which the PBEsol is used. By using the optimized crystal structure, the band gap, the electron effective mass, the hole effective mass, and the absorption coefficient spectrum of YZn₃N₃ were calculate by the first-principles calculation.

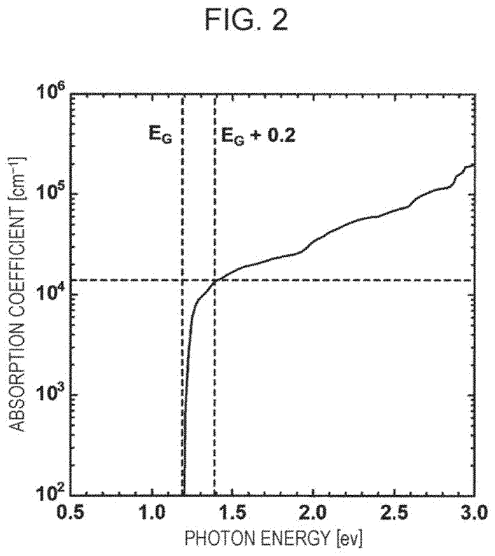

The bottom of the conduction band in the energy dispersion was assumed to have a parabola shape, and the electron effective mass was calculated from the density of states. As is the case described above, the top of the valence band in the energy dispersion is assumed to have a parabola shape, and the hole effective mass was calculated by the density of states. The absorption coefficient spectrum was calculated from a dielectric function obtained by the first-principles calculation using the PBEsol. FIG. 2 shows the absorption coefficient spectrum of YZn₃N₃ calculated by the first-principles calculation using the PBEsol. Table 1 shows the band gap, the electron effective mass, and the hole effective mass of YZn₃N₃ calculated using the hybrid functional. Table 1 also shows the band gap of YZn₃N₃ calculated using the PBEsol and an absorption coefficient at an energy higher than the band gap described above by 0.2 eV.

As has been well known in this technical field, the “absorption coefficient at an energy higher than the band gap of YZn₃N₃ by 0.2 eV” can be obtained from the graph (see FIG. 2) of the absorption coefficient spectrum calculated as described above. The horizontal axis and the vertical axis of the graph represent the energy and the absorption coefficient, respectively. When the energy is lower than the band gap, the absorption coefficient is 0. The “absorption coefficient at an energy higher than the band gap of YZn₃N₃ by 0.2 eV” is an absorption coefficient corresponding to an energy higher than the band gap of YZn₃N₃ by 0.2 eV. As described later in Table 1, since the band gap of YZn₃N₃ calculated using the PBEsol is 1.2 eV, the “absorption coefficient at an energy higher than the band gap of YZn₃N₃ by 0.2 eV” indicates an absorption coefficient at an energy of 1.4 eV. As for the electron effective mass, in Table 1, a ratio of the electron effective mass (me*) to the electron rest mass (m0) is shown. In other words, a ratio (me*/m0) is shown in Table 1 as the electron effective mass. As for the hole effective mass, in Table 1, a ratio of the hole effective mass (mh*) to the electron rest mass (m0) is shown. In other words, a ratio (mh*/m0) is shown in Table 1 as the hole effective mass. FIG. 2 shows the absorption coefficient spectrum of YZn₃N₃.

As apparent from Table 1 and FIG. 2, in a light energy conversion element, such as a solar cell or a solar water splitting device, YZn₃N₃ has a band gap suitable for a material of a light energy conversion layer. Furthermore, in the light energy conversion element, electrons and holes excited by light are required to reach electrodes without being deactivated. As is the case described above, without being deactivated, the electrons and the holes excited by light are also required to reach interfaces before a chemical reaction occurs. Hence, in the light energy conversion material, the electron effective mass and the hole effective mass are both preferably small. For example, the ratio of the electron effective mass to the electron rest mass is preferably lower than 1.5. Hereinafter, the ratio of the electron effective mass to the electron rest mass is called an electron effective mass ratio. As is the case described above, the ratio of the hole effective mass to the electron rest mass is preferably lower than 1.5. Hereinafter, the ratio of the hole effective mass to the electron rest mass is called a hole effective mass ratio. YZn₃N₃ has an electron effective mass ratio of less than 1 and a hole effective mass ratio of less than 1. Hence, YZn₃N₃ can be said to have a very small effective mass as the semiconductor material. In addition, at an energy higher than the band gap of YZn₃N₃ calculated using the PBEsol by 0.2 eV, that is, at an energy of 1.4 eV, YZn₃N₃ has a large absorption coefficient of 1.4×10⁴ cm⁻¹ (see FIG. 2). As apparent from FIG. 2, the absorption coefficient at an energy higher than the band gap (that is, 1.2 eV) of YZn₃N₃ by 0.2 eV (that is, 1.4 eV) is 1.4×10⁴ cm⁻¹. As shown in FIG. 2, the absorption coefficient at an energy of 1.4 eV or more is 1.4×10⁴ cm⁻¹ or more. Hence, YZn₃N₃ has a large absorption coefficient of 1.4×10⁴ cm⁻¹ or more in an energy range of higher than or equal to 1.4 eV. It has been known that the band gap calculated using the GGA (including the PBEsol) is smaller than the band gap of an actually synthesized compound. As one example, the band gap calculated using the GGA (including the PBEsol) may be approximately 0.5 times the band gap of an actually synthesized compound in some cases.

In addition, by the hybridization of the 3d orbital of Zn and the 2p orbital of N, the valence band is formed by the antibonding orbital. When defects are introduced into a material having the electron structure as described above, it is expected that a deep level is not formed in the material but a shallow level is formed therein. The deep level functions as a recombination site of carriers and has an adverse effect to carrier transport characteristics. Hence, even if defects are present, the material for the light energy conversion element preferably has characteristics to form a shallow level.

As has thus been described, YZn₃N₃ is very promising as a material for the light energy conversion element. That is, when YZn₃N₃ is used for a first light energy conversion layer of a multi-junction type light energy conversion element which will be described later, the light energy conversion element efficiently absorbs solar light having appropriate wavelengths. As a result, the light energy conversion element can show preferable carrier transfer characteristics. As described above, the light energy conversion element can realize a high energy conversion efficiency.

TABLE 1

| | HYBRID | | | PBEsol | |
|---|---|---|---|---|---|
| | FUNCTIONAL | | | | ABSORPTION |
| | | EFFECTIVE | | | COEFFICIENT AT |
| Approximation | BAND | MASS | | BAND | ENERGY HIGHER |
| ELECTRONIC | GAP | me*/ | mh*/ | GAP | THAN BAND GAP |
| PROPERTIES | [eV] | m0 | m0 | [eV] | BY 0.2 eV [cm⁻¹] |
| VALUES OF | 1.8 | 0.041 | 0.97 | 1.2 | 1.4 × 10⁴ |
| ELECTRONIC | | | | | |
| PROPERTIES | | | | | |

Next, a method for manufacturing an inorganic compound semiconductor according to the first embodiment will be described. As one example, the method for manufacturing an inorganic compound semiconductor according to the first embodiment includes a step (a) of forming the inorganic compound semiconductor containing Y, Zn, and N by a sputtering method using at least one raw material containing Y and Zn in a nitrogen-containing atmosphere.

An inorganic compound semiconductor (such as YZn₃N₃) whose synthesis has not been reported before is synthesized by the above manufacturing method. Since the above manufacturing method includes no complicated steps, a specific apparatus is not required. Hence, the inorganic compound semiconductor containing Y, Zn, and N can be manufactured by the above manufacturing method at a low cost.

A material used as the raw material is not particularly limited. As an example of the material used as the raw material, for example, there may be mentioned a single metal (such as Y or Zn), an alloy (such as YZn₃ or YZn₅), an oxide (such as ZnO or Y₂O₃), a nitride (such as Zn₃N₂ or YN), a metal salt (such as a carbonate salt or a chloride), or a mixture therebetween.

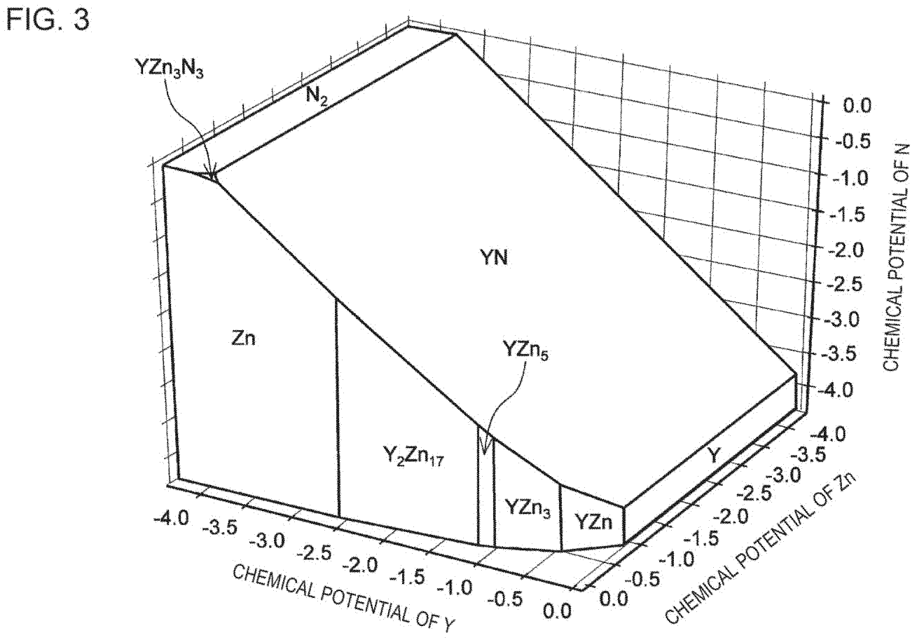

In general, in a nitride synthesis, nitrogen molecules are not likely to react. In order to increase the reactivity of nitrogen molecules, for example, at least one selected from the groups consisting of a chemical potential of nitrogen (hereinafter, referred to as “nitrogen potential”) and a reactivity of the raw material may be improved. FIG. 3 shows a phase diagram of a chemical potential space of a Y—Zn—N coordinate system. From FIG. 3, it is understood that for the synthesis of YZn₃N₃, a high nitrogen potential is required. The sputtering method can improve the nitrogen potential. The reason for this is that in the vicinity of a target, a plasmized nitrogen gas reacts with the target.

### Second Embodiment

A light energy conversion element according to a second embodiment of the present disclosure includes a light energy conversion layer containing the inorganic compound semiconductor according to the first embodiment. The light energy conversion element may have a two-layer structure in which two different light energy conversion layers are laminated to each other. That is, the light energy conversion element according to the second embodiment may includes a first light energy conversion layer containing the inorganic compound semiconductor according to the first embodiment and a second light energy conversion layer containing a light energy conversion material. The light energy conversion material contained in the second light energy conversion layer has a band gap narrower than that of the inorganic compound semiconductor according to the first embodiment.

Hereinafter, as one example of the multi-junction type light energy conversion element, a light energy conversion element including two light energy conversion layers will be described.

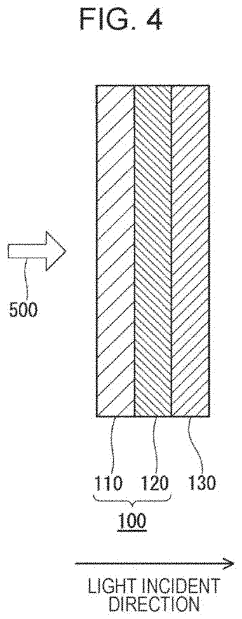

FIG. 4 is a cross-sectional view of a light energy conversion element 100 according to the second embodiment. As shown in FIG. 4, light 500 is incident on the light energy conversion element 100 in a predetermined direction. The light energy conversion element 100 includes a first light energy conversion layer 110 and a second light energy conversion layer 120. The second light energy conversion layer 120 is disposed at a downstream side than the first light energy conversion layer 110 in a light incident direction toward the light energy conversion element 100. In FIG. 4, the light energy conversion element 100 is formed from only the first light energy conversion layer 110 and the second light energy conversion layer 120. However, the light energy conversion element 100 may further include at least one element other than the first light energy conversion layer 110 and the second light energy conversion layer 120. In FIG. 4, reference numeral 130 represents a first electrode 130.

As shown in FIG. 4, the light energy conversion element 100 has a two-layer structure in which the two different light energy conversion layers are laminated to each other. A multi-junction type light energy conversion element including two light energy conversion layers is called a tandem type light energy conversion element in some cases.

The first light energy conversion layer 110 and the second light energy conversion layer 120 contain a first light energy conversion material and a second light energy conversion material, respectively. The first light energy conversion material and the second light energy conversion material are each required to have an appropriate band gap. The first light energy conversion material is able to have a band gap of higher than or equal to 1.5 eV and lower than or equal to 2.5 eV. The second light energy conversion material is able to have a band gap of higher than or equal to 0.8 eV and lower than or equal to 1.4 eV.

The first light energy conversion layer 110 contains the inorganic compound semiconductor according to the first embodiment as the first light energy conversion material. As described in the first embodiment, YZn₃N₃ has an appropriate band gap as the first light energy conversion material.

The second light energy conversion material has a band gap narrower than that of the first light energy conversion material. The difference in band gap between the first light energy conversion material and the second light energy conversion material may be higher than or equal to 0.2 eV and lower than or equal to 1.0 eV. For example, the second light energy conversion material is silicon (Si).

In FIG. 4, the first electrode 130 is disposed at a downstream side than the second light energy conversion layer 120 in the light incident direction. However, the position of the first electrode 130 is not limited to that shown in FIG. 4. The first electrode 130 may be disposed at an upstream side than the first light energy conversion layer 110 in the light incident direction. The first electrode 130 may be an electrically conductive body having a transparency through which the light passes. An example of the light may be visible light. When the first electrode 130 is disposed at an upstream side than the second light energy conversion layer 120 in the light incident direction, the first electrode 130 is required to be an electrically conductive body having a transparency through which the light passes.

The number of the light energy conversion layers included in the light energy conversion element 100 shown in FIG. 4 is two. However, the multi-junction type light energy conversion element of the present disclosure may include at least three light energy conversion layers. When the multi-junction type light energy conversion element includes at least three light energy conversion layers, the first light energy conversion layer 110 and the second light energy conversion layer 120 are located at an upstream side and a downstream side, respectively, in a light incident direction toward the multi-junction type light energy conversion element. In the light incident direction, another light energy conversion layer may be further provided at an upstream side than the first light energy conversion layer 110. Between the first light energy conversion layer 110 and the second light energy conversion layer 120, another light energy conversion layer may be further provided. Another light energy conversion layer may be further provided at a downstream side than the second light energy conversion layer 120. In FIG. 4, the first light energy conversion layer 110 and the second light energy conversion layer 120 are in direct contact with each other. However, between the first light energy conversion layer 110 and the second light energy conversion layer 120, a bonding layer may also be provided.

The light energy conversion element 100 of the present disclosure may not be a multi-junction type. That is, the number of the light energy conversion layers included in the light energy conversion element 100 may be one. It goes without saying that the light energy conversion layer described above contains the inorganic compound semiconductor according to the first embodiment.

### Third Embodiment

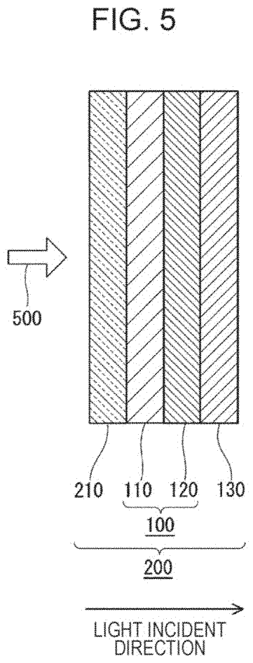

FIG. 5 is a cross-sectional view of a device 200 according to a third embodiment of the present disclosure. The device 200 shown in FIG. 5 includes the light energy conversion element 100 according to the second embodiment. The device 200 includes, besides the first electrode 130, a second electrode 210. The first electrode 130 has been already described in the first embodiment. As shown in FIG. 5, the first electrode 130 is disposed at a downstream side than the second light energy conversion layer 120 in the light incident direction. However, the first electrode 130 may be disposed at an upstream side than the first light energy conversion layer 110 in the light incident direction. The light energy conversion element 100 including the first light energy conversion layer 110 and the second light energy conversion layer 120 is provided between the first electrode 130 and the second electrode 210.

In the device 200, the light energy conversion element 100 is used, and light radiated to the light energy conversion element 100 is converted into an electric power. According to the device 200 shown in FIG. 5, in the light incident direction, the second electrode 210 is disposed at an upstream side than the light energy conversion element 100. The second electrode 210 is an electrically conductive body having a transparency to light (such as visible light). When the first electrode 130 is disposed at an upstream side than the first light energy conversion layer 110 in the light incident direction, the second electrode 210 is disposed at a downstream side than the second light energy conversion layer 120. Hence, in the case described above, the first electrode 130 has a transparency to light (such as visible light), and the second electrode 210 may not have a transparency to light (such as visible light).

When light is radiated to the device 200, a short wavelength component included in the light passing through the second electrode 210 is absorbed by the first light energy conversion layer 110. A long wavelength component not absorbed by the first light energy conversion layer 110 is absorbed by the second light energy conversion material in the second light energy conversion layer 120. The light energy absorbed by the first light energy conversion layer 110 and the second light energy conversion layer 120 is converted into electric energy, and the electric energy thus converted is extracted through the first electrode 130 and the second electrode 210.

### Fourth Embodiment

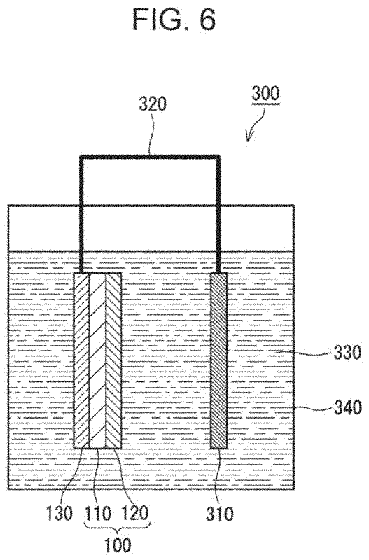

FIG. 6 is a cross-sectional view of a device 300 according to a fourth embodiment of the present disclosure. The device 300 shown in FIG. 6 includes the light energy conversion element 100 according to the second embodiment. The device 300 further includes a first electrode 130, a second electrode 310, a liquid 330, and a container 340. In the device 300, when light is radiated to the light energy conversion element 100, water splitting occurs. The first electrode 130 is the same as described in the first embodiment.

The second electrode 310 is electrically connected to the first electrode 130 of the light energy conversion element 100 with a conducting wire 320 interposed therebetween.

The liquid 330 is water or an electrolyte solution. The electrolyte solution is acidic or basic. In particular, as the electrolyte solution, for example, an aqueous sulfuric acid solution, an aqueous sodium sulfate solution, an aqueous sodium carbonate solution, a phosphoric acid buffer solution, or a boric acid buffer solution may be mentioned.

The container 340 receives the light energy conversion element 100, the first electrode 130, the second electrode 310, and the liquid 330. The container 340 may be transparent. In particular, the container 340 may be at least partially transparent so that light is transmitted from the outside to the inside of the container 340.

When light is radiated to the light energy conversion element 100, oxygen or hydrogen is generated on the surface of the light energy conversion element 100, and on the surface of the second electrode 310, hydrogen or oxygen is generated. Light, such as solar light, passes through the container 340 and reaches the light energy conversion element 100. In the conduction band and the valence band of the light energy conversion material of each of the first light energy conversion layer 110 and the second light energy conversion layer 120, both of which absorb the light, electrons and holes are generated, respectively. By those electrons and holes, a water splitting reaction occurs. When the semiconductor contained as the light energy conversion material of the light energy conversion element 100 is an n-type semiconductor, on the surface of the light energy conversion element 100, water is split as shown in the following reaction formula (1), and oxygen is generated. At the same time, on the surface of the second electrode 310, as shown by the following reaction formula (2), hydrogen is generated. When the semiconductor contained as the light energy conversion material of the light energy conversion element 100 is a p-type semiconductor, on the surface of the second electrode 310, water is split as shown in the following reaction formula (1), and oxygen is generated. At the same time, on the surface of the light energy conversion element 100, as shown by the following reaction formula (2), hydrogen is generated.

4h⁺+2H₂O→O₂↑+4H⁺ (1)

(h⁺ represents a hole)

4e⁻+4H⁺→2H₂↑ (2)

In the device 300 shown in FIG. 6, after passing through the first electrode 130, light may reach the light energy conversion element 100. Alternatively, after passing through the second electrode 310, light may reach the light energy conversion element 100. When the light passing through the second electrode 310 reaches the light energy conversion element 100, the second electrode 310 has a transparency to the light (such as visible light).

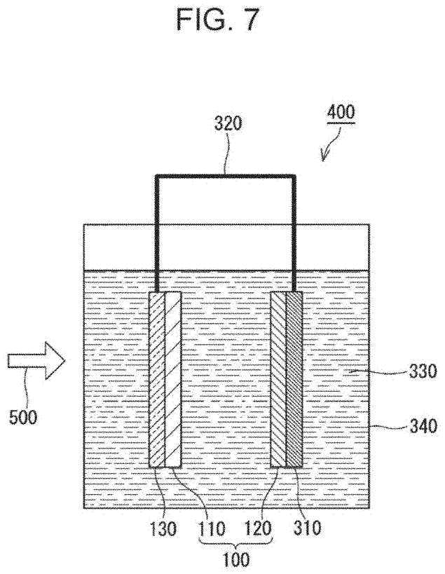

The device of the fourth embodiment is not limited to the device 300 shown in FIG. 6. As a device 400 shown in FIG. 7, the liquid 330 may be disposed between the first light energy conversion layer 110 and the second light energy conversion layer 120. In order to further improve the light absorption coefficient, the first light energy conversion layer 110 may have a surface area different from that of the second light energy conversion layer 120. The second light energy conversion layer 120 may have a surface area larger than that of the first light energy conversion layer 110.

### Examples

Hereinafter, with reference to Examples, the inorganic compound semiconductor of the present disclosure will be described in more detail.

(Sample 1)

A thin film was grown on a substrate by a co-sputtering method using single metals of Y and Zn as targets. The substrate was a non-alkaline glass (trade name: EAGLE XG, manufactured by Corning Incorporated). Into a chamber, a mixture gas of nitrogen (95 percent by mole) and hydrogen (5 percent by mole) was supplied at a flow rate of 25 sccm. A pressure inside the chamber in the sputtering was maintained at 2 Pa. During the growth of the thin film, a temperature of the substrate was maintained at 200° C. An RF input power supplied to the Y target was 30 W. An RF input power supplied to the Zn target was 20 W. The growth of the thin film was performed for 20 hours. As described above, the thin film was formed as Sample 1. After the growth of the thin film of Sample 1, the pressure of the mixture gas of nitrogen and hydrogen was maintained at 2 Pa.

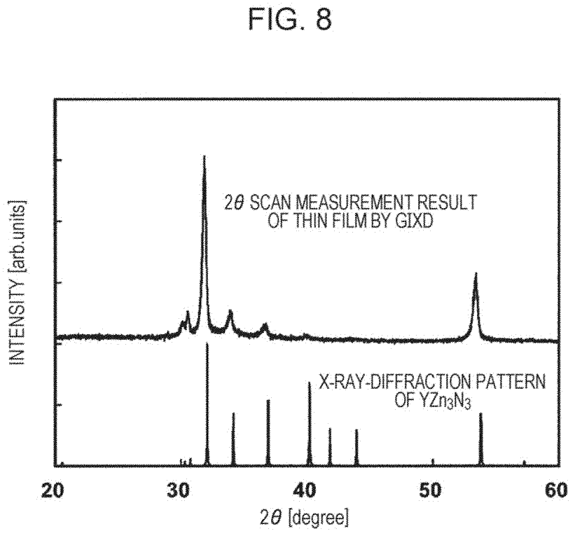

FIG. 8 shows an actual oblique incident X-ray diffraction pattern of the thin film of Sample 1 and an X-ray diffraction pattern of YZn₃N₃ calculated using a crystal structure predicted by the first-principles calculation. In the conversion from the predicted crystal structure to the X-ray diffraction pattern, crystal structure visualization software program VESTA and X-ray diffraction analysis software program RIETAN were used. Hereinafter, the “oblique incident X-ray diffraction” is called GIXD. In the GIDX measurement, CuKα line was used, the measurement wavelength was 0.15405 nm, and an automatic horizontal type multi-purpose X-ray diffraction apparatus (trade name; SmartLab, manufactured by Rigaku Corporation) was used. The incident angle ω was maintained at 0.5°.

As shown in FIG. 8, the actual oblique incident X-ray diffraction pattern of the thin film of Sample 1 approximately coincides with the X-ray diffraction pattern of YZn₃N₃ calculated using the crystal structure predicted by the first-principles calculation. A molar ratio of Zn to Y in the thin film of Sample 1 (that is, a molar ratio of Zn/Y) was measured by an energy dispersive X-ray analysis method (hereinafter, referred to as “EDX method”). As a result, the molar ratio of Zn to Y was 3.0. Those results indicate that YZn₃N₃ whose synthesis has not been reported before was synthesized.

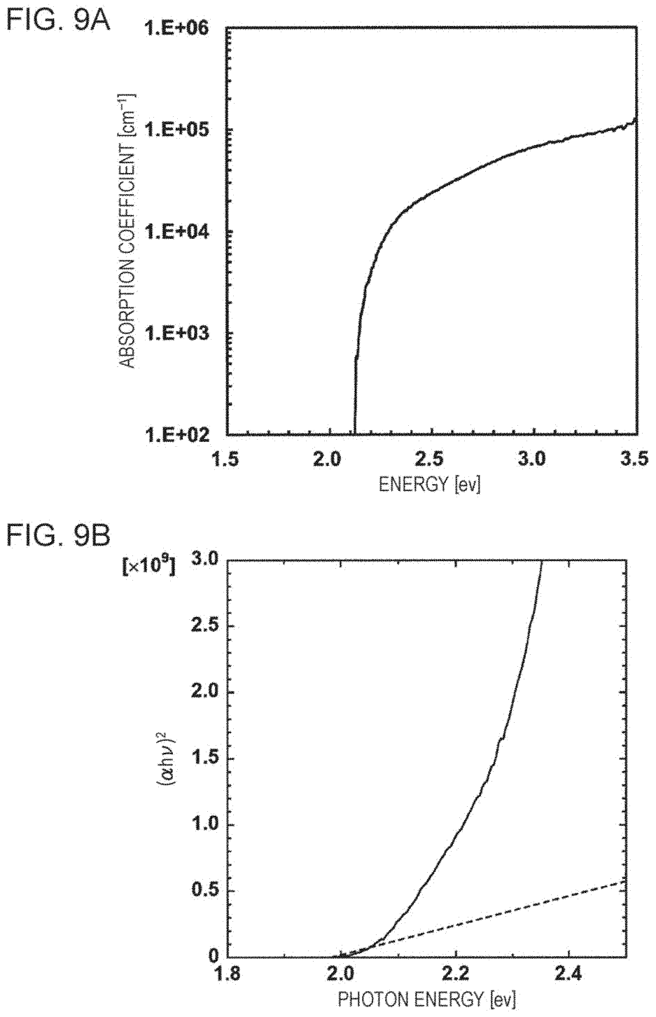

FIG. 9A shows an absorption coefficient spectrum of the thin film of Sample 1. FIG. 9B shows a Tauc plot (hν vs. (ahν)²) of the absorption coefficient spectrum of the thin film of Sample 1. The absorption coefficient spectrum shown in FIG. 9A was obtained such that after the transmittance of the thin film of Sample 1 through which light passes and the reflectance thereof were measured, the measurement results of the transmittance and the reflectance were converted to the absorption coefficient spectrum. FIG. 9B shows that the thin film of Sample 1 is a direct transition semiconductor having a band gap of 2.0 eV. As shown in FIG. 9A, the absorption coefficient has a steep rise. From the results described above, it was shown that the thin film of Sample 1 is an inorganic compound semiconductor suitable for a light energy conversion material of the light energy conversion element.

(Sample 2)

Except for that the RF input power supplied to the Zn target was 30 W, a thin film was grown on a substrate in a manner similar to that of Sample 1. As described above, the thin film of Sample 2 was obtained.

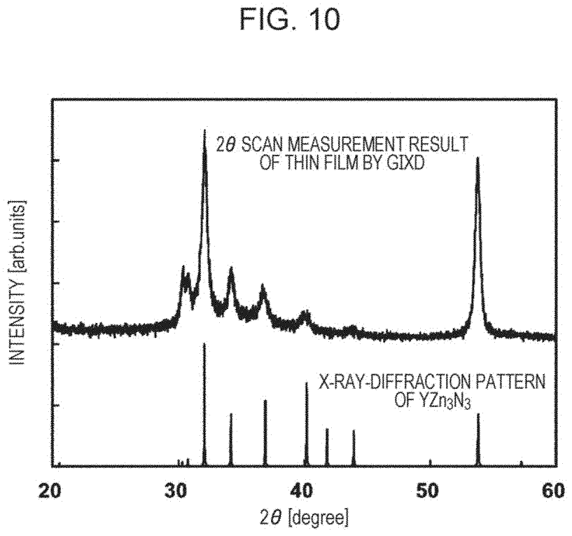

FIG. 10 shows an actual oblique incident X-ray diffraction pattern of the thin film of Sample 2 and the X-ray diffraction pattern of YZn₃N₃ calculated using the crystal structure predicted by the first-principles calculation. Sample 2 was subjected to GIXD in a manner similar to that of Sample 1. As shown in FIG. 10, as was the case of Sample 1, the actual oblique incident X-ray diffraction pattern of the thin film of Sample 2 coincides with the X-ray diffraction pattern of YZn₃N₃ calculated using the crystal structure predicted by the first-principles calculation. This result indicates that an inorganic compound having a crystal structure similar to that of YZn₃N₃ whose synthesis has not been reported before and containing Y, Zn, and N was synthesized.

A molar ratio of Zn to Y of the thin film of Sample 2 was measured by an EDX method. As a result, the molar ratio of Zn to Y was 4.8.

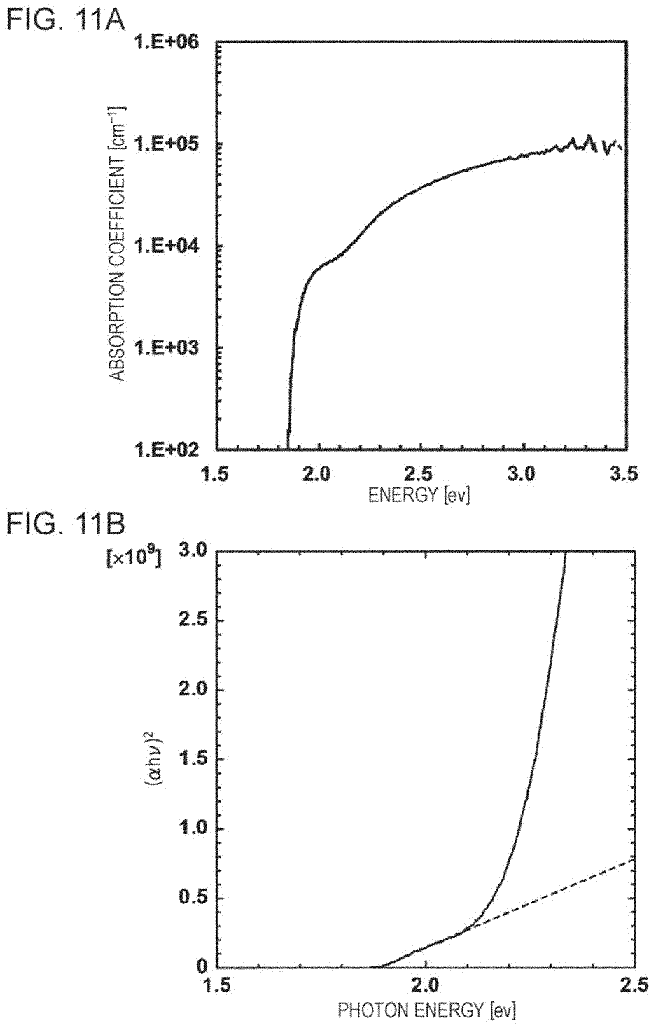

FIG. 11A shows an absorption coefficient spectrum of the thin film of Sample 2. FIG. 11B shows a Tauc plot (hν vs. (ahν)²) of the absorption coefficient spectrum of the thin film of Sample 2. The absorption coefficient spectrum shown in FIG. 11A was obtained such that after the transmittance and the reflectance of the thin film of Sample 2 were measured, the measurement results of the transmittance and the reflectance of the thin film were converted to the absorption coefficient spectrum. FIG. 11B shows that the thin film of Sample 2 is a direct transition semiconductor having a band gap of 1.9 eV. As shown in FIG. 11A, the absorption coefficient has a steep rise. From the results described above, it was shown that the thin film of Sample 2 is an inorganic compound semiconductor suitable for a light energy conversion material of the light energy conversion element.

(Sample 3)

Except for that the RF input power supplied to the Zn target was 15 W, a thin film was grown on a substrate in a manner similar to that of Sample 1. As described above, the thin film of Sample 3 was obtained.

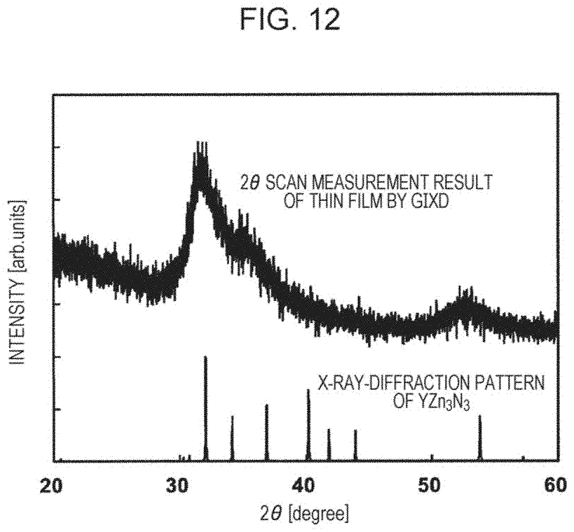

FIG. 12 shows an actual oblique incident X-ray diffraction pattern of the thin film of Sample 3 and the X-ray diffraction pattern of YZn₃N₃ calculated using the crystal structure predicted by the first-principles calculation. Sample 3 was subjected to GIXD in a manner similar to that of Sample 1. As shown in FIG. 12, in the actual oblique incident X-ray diffraction pattern of the thin film of Sample 3, vague peaks were observed.

A molar ratio of Zn to Y of the thin film of Sample 3 was measured by an EDX method. As a result, the molar ratio of Zn to Y was 2.4.

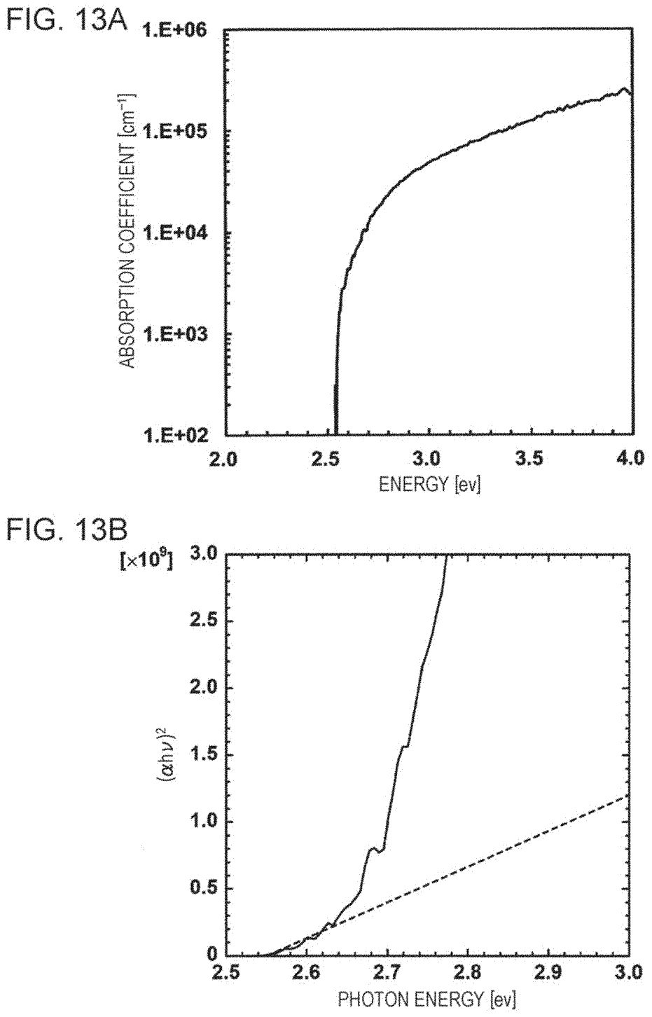

FIG. 13A shows an absorption coefficient spectrum of the thin film of Sample 3. FIG. 13B shows a Tauc plot (hν vs. (ahν)²) of the absorption coefficient spectrum of the thin film of Sample 3. The absorption coefficient spectrum shown in FIG. 13A was obtained such that after the transmittance and the reflectance of the thin film of Sample 3 were measured, the measurement results of the transmittance and the reflectance were converted to the absorption coefficient spectrum. FIG. 13B shows that the thin film of Sample 3 is a direct transition semiconductor having a band gap of 2.6 eV. As shown in FIG. 13A, the absorption coefficient has a steep rise. From the results described above, it was shown that the thin film of Sample 3 is an inorganic compound semiconductor usable as a light energy conversion material contained in the light energy conversion element.

(Sample 4)

Except for that the RF input power supplied to the Zn target was 45 W, a thin film was grown on a substrate in a manner similar to that of Sample 1.

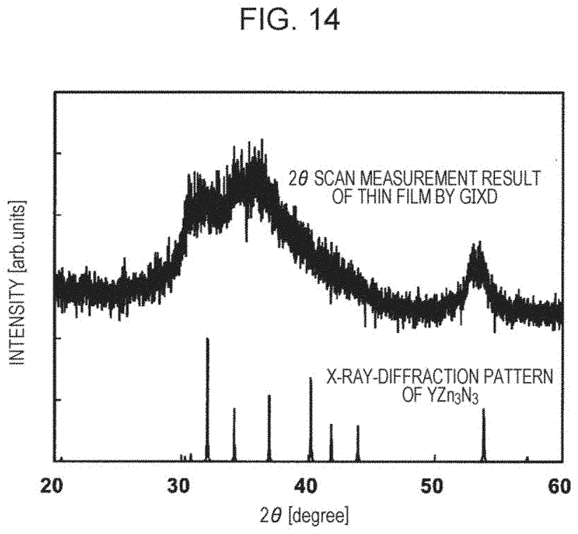

FIG. 14 shows an actual oblique incident X-ray diffraction pattern of the thin film of Sample 4 and the X-ray diffraction pattern of YZn₃N₃ calculated using the crystal structure predicted by the first-principles calculation. Sample 4 was subjected to GIXD in a manner similar to that of Sample 1. As shown in FIG. 14, in the actual oblique incident X-ray diffraction pattern of the thin film of Sample 4, vague peaks were observed.

A molar ratio of Zn to Y of the thin film of Sample 4 was measured by an EDX method. As a result, the molar ratio of Zn to Y was 7.3.

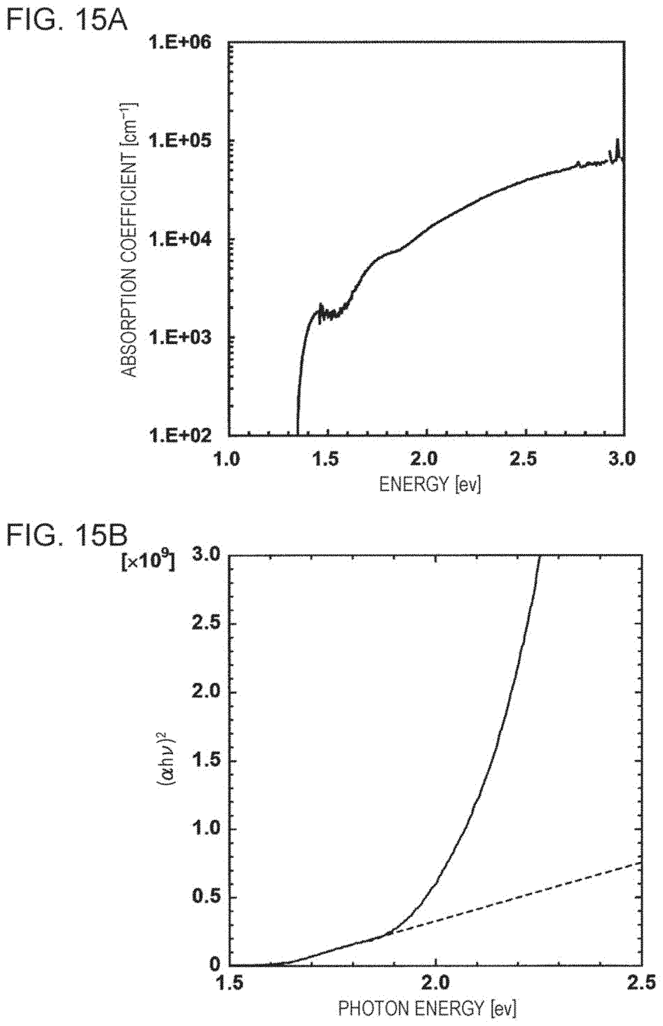

FIG. 15A shows an absorption coefficient spectrum of the thin film of Sample 4. FIG. 15B shows a Tauc plot (hν vs. (ahν)²) of the absorption coefficient spectrum thus measured. The absorption coefficient spectrum shown in FIG. 15A was obtained such that after the transmittance and the reflectance of the thin film of Sample 4 were measured, the measurement results of the transmittance and the reflectance were converted to the absorption coefficient spectrum. FIG. 15B shows that the thin film of Sample 4 is a direct transition semiconductor having a band gap of 1.6 eV. As shown in FIG. 15A, the absorption coefficient has a steep rise. From the results described above, it was shown that the thin film of Sample 4 is an inorganic compound semiconductor usable as a light energy conversion material contained in the light energy conversion element.

In the following Table 2, the molar ratio of Zn to Y and the band gap of the inorganic compound semiconductor according to each of Samples 1 to 4 are shown.

TABLE 2

| SAMPLE | Zn/Y (MOLAR RATIO) | BAND GAP (eV) |
|---|---|---|
| 3 | 2.4 | 2.6 |
| 1 | 3.0 | 2.0 |
| 2 | 4.8 | 1.9 |
| 4 | 7.3 | 1.6 |

As apparent from Table 2, as the molar ratio of Zn to Y is decreased, the band gap of the thin film of the inorganic compound semiconductor is increased.

The inorganic compound semiconductor of the present disclosure can be used as a light energy conversion material. The inorganic compound semiconductor of the present disclosure may be preferably used for a solar cell or a solar water splitting device. The inorganic compound semiconductor of the present disclosure may also be used for a semiconductor device, such as a diode, a transistor, or a sensor.

What is claimed is:

1. An inorganic compound semiconductor consisting essentially of yttrium, zinc, and nitrogen.

2. The inorganic compound semiconductor according to claim 1,
wherein the inorganic compound semiconductor has a hexagonal crystal structure.

3. The inorganic compound semiconductor according to claim 1,
wherein a molar ratio of the zinc to the yttrium is larger than or equal to 2.5 and smaller than or equal to 6.

4. The inorganic compound semiconductor according to claim 3,
wherein the molar ratio is larger than or equal to 3.0 and smaller than or equal to 4.8.

5. The inorganic compound semiconductor according to claim 1,
wherein the inorganic compound semiconductor is represented by a chemical formula of YZn₃N₃.

6. The inorganic compound semiconductor according to claim 1,
wherein the inorganic compound semiconductor has a band gap of higher than or equal to 1.7 eV and lower than or equal to 2.5 eV.

7. A light energy conversion element comprising:
a first light energy conversion layer containing the inorganic compound semiconductor according to claim 1.

8. The light energy conversion element according to claim 7, further comprising:
a second light energy conversion layer containing a light energy conversion material,
wherein the light energy conversion material has a band gap narrower than that of the inorganic compound semiconductor.

9. A method for manufacturing an inorganic compound semiconductor, comprising:
forming an inorganic compound semiconductor containing yttrium, zinc, and nitrogen by a sputtering method using a raw material containing yttrium and zinc in a nitrogen-containing atmosphere.
